(19) United States
(12) Patent Application Publication
(10) Pub. No.: US 2024/0128400 A1
(43) Pub. Date: Apr. 18, 2024

(54) METHOD TO IMPROVE THE PERFORMANCE OF GALLIUM-CONTAINING MICRON-SIZED LIGHT-EMITTING DEVICES

(71) Applicant: The Regents of the University of California, Oakland, CA (US)

(72) Inventors: Steven P. DenBaars, Goleta, CA (US); Matthew S. Wong, Santa Barbara, CA (US)

(73) Assignee: The Regents of the University of California, Oakland, CA (US)

(21) Appl. No.: 18/547,752

(22) PCT Filed: Mar. 4, 2022
(86) PCT No.: PCT/US22/18904

§ 371 Date: Aug. 24, 2023

Related U.S. Application Data
(60) Provisional application No. 63/157,033, filed on Mar. 5, 2021.

(51) Int. Cl. H01L 33/00; H01L 33/32; H01L 33/44

(52) U.S. Cl. CPC H01L 33/0075; H01L 33/32; H01L 33/44

(57) ABSTRACT

Grow gallium-containing semi-conductor layers are grown on a substrate, wherein the gallium-containing semiconductor layers comprise AlₓGa_{y}In_{z}NᵥP_{w}Asᵤ, where 0≤x≤1, 0≤y≤1, 0≤z≤1, 0≤v≤1, 0≤w≤1, 0≤u≤1, v+w+u=1, and x+y+z=1. Dry etching of the gallium-containing semiconductor layers exposes sidewalls of the layers. Surface treatments are performed to recover from damage to the sidewalls resulting from the dry etching. Dielectric materials are deposited on the sidewalls, for example, by atomic layer deposition (ALD), to passivate the sidewalls. The resulting gallium-containing semiconductor layers have an improvement in optical efficiency as compared to gallium-containing semiconductor layers that are not subjected to the surface treatments and the deposition of the dielectric materials.

### CROSS REFERENCE TO RELATED APPLICATIONS

This application claims the benefit under 35 U.S.C. Section 119(e) of the following co-pending and commonly-assigned applications:

U.S. Provisional Application Ser. No. 63/157,033, filed on Mar. 5, 2021, by Steven P. DenBaars and Matthew S. Wong, entitled “METHOD TO IMPROVE THE PERFORMANCE OF GALLIUM-CONTAINING MICRON-SIZED LIGHT-EMITTING DEVICES,” attorneys' docket number G&C 30794.0798USP1 (UC 2021-870-1);

which application is incorporated by reference herein.

This application is related to the following co-pending and commonly-assigned applications:

U.S. Utility patent application Ser. No. 16/757,920, filed on Apr. 21, 2020, by Matthew S. Wong, David Hwang, Abdullah Alhassan, and Steven P. DenBaars, entitled “REDUCTION IN LEAKAGE CURRENT AND INCREASE IN EFFICIENCY OF III-NITRIDE LEDS BY SIDEWALL PASSIVATION USING ATOMIC LAYER DEPOSITION,” attorney's docket number 30794.0667USWO (UC 2018-256-2), which claims the benefit under 35 U.S.C. Section 365(c) of PCT International Patent Application No. PCT/US18/58362, filed on Oct. 31, 2018, by Matthew S. Wong, David Hwang, Abdullah Alhassan, and Steven P. DenBaars, entitled “REDUCTION IN LEAKAGE CURRENT AND INCREASE IN EFFICIENCY OF III-NITRIDE LEDS BY SIDEWALL PASSIVATION USING ATOMIC LAYER DEPOSITION,” attorney's docket number 30794.0667WOU1 (UC 2018-256-2), which application claims the benefit under 35 U.S.C. Section 119(e) of U.S. Provisional Patent Application No. 62/580,287, filed on Nov. 1, 2017, by Matthew S. Wong, David Hwang, Abdullah Alhassan, and Steven P. DenBaars, entitled “REDUCTION IN LEAKAGE CURRENT AND INCREASE IN EFFICIENCY OF III-NITRIDE LEDS BY SIDEWALL PASSIVATION USING ATOMIC LAYER DEPOSITION,” attorney's docket number 30794.0667USP1 (UC 2018-256-1);

U.S. Utility patent application Ser. No. 17/281,700, filed on Mar. 31, 2021, by Tal Margalith, Matthew S. Wong, Lesley Chan, and Steven P. DenBaars, entitled “MICRO-LEDS WITH ULTRA-LOW LEAKAGE CURRENT,” attorney's docket number 30794.0707USWO (UC 2019-393-2), which claims the benefit under 35 U.S.C. Section 365(c) of PCT International Application Serial No. PCT/US19/59163, filed on Oct. 31, 2019, by Tal Margalith, Matthew S. Wong, Lesley Chan, and Steven P. DenBaars, entitled “MICRO-LEDS WITH ULTRA-LOW LEAKAGE CURRENT,” attorneys' docket number G&C 30794.0707WOU1 (UC 2019-393-2), which application claims the benefit under 35 U.S.C. Section 119(e) of U.S. Provisional Patent Application Ser. No. 62/756,252, filed on Nov. 6, 2018, by Tal Margalith, Matthew S. Wong, Lesley Chan, and Steven P. DenBaars, entitled “MICRO-LEDS WITH ULTRA-LOW LEAKAGE CURRENT,” attorneys' docket number G&C 30794.0707USP1 (UC 2019-393-1); and

PCT International Patent Application Serial No. PCT/US20/58234, filed on Oct. 30, 2020, by Matthew S. Wong, Jordan M. Smith and Steven P. DenBaars, entitled “METHOD TO IMPROVE THE PERFORMANCE OF GALLIUM-CONTAINING LIGHT-EMITTING DEVICES,” attorneys' docket number G&C 30794.0754WOU1 (UC 2020-086-2), which application claims the benefit under 35 U.S.C. Section 1I9(e) of co-pending and commonly-assigned application U.S. Provisional Patent Application Ser. No. 62/927,859, filed on Oct. 30, 2019, by Matthew S. Wong, Jordan M. Smith and Steven P. DenBaars, entitled “METHOD TO IMPROVE THE PERFORMANCE OF GALLIUM-CONTAINING LIGHT-EMITTING DEVICES,” attorneys' docket number G&C 30794.0754USP1 (UC 2020-086-1); all of which applications are incorporated by reference herein.

### BACKGROUND OF THE INVENTION

### 1. Field of the Invention

This invention relates generally to light emitting diodes (LEDs), and more specifically, to a method to improve the performance of Gallium-containing micron-sized LEDs.

### 2. Description of the Related Art

Micron-sized devices, including light-emitting diodes (LEDs) and micro-LEDs (μLEDs), have gained increasing attention due to their possible use in next-generation display applications. For most display applications, red, green, and blue colors are required. Typically, III-nitride and conventional III-V semiconductor materials, namely, AlGaInN and AlGaInPAs, respectively, are used for micron-sized LEDs, where the light-emitting area is defined by dry etching.

One main problem of creating micron-sized LEDs is the efficiency loss due to the damage from the dry etching step, where non-radiative recombination is introduced into the devices, and thus reduces the light output from the devices. Between the two semiconductor material systems, AlGaInPAs suffers severely in the efficiency loss because of the higher surface recombination velocity and greater minority carrier diffusion length. The efficiency loss in micron-sized LEDs serves as a major barrier, since the micron-sized LEDs' efficiency decreases with smaller device dimensions.

Thus, there is a need in the art for improved methods for fabricating AlGaInN-based and AlGaInPAs-based micron-sized LEDs. The present invention satisfies this need.

### SUMMARY OF THE INVENTION

To overcome the limitations of the prior art described above, the present invention discloses a method to improve the performance of gallium-containing micron-sized LEDs. Gallium-containing semiconductor layers are grown on a substrate, wherein the gallium-containing semiconductor layers comprise AlₓGa_{y}In_{z}NᵥP_{w}Asᵤ, where 0≤x≤1, 0≤y≤1, 0≤z≤1, 0≤v≤1, 0≤w≤1, 0≤u≤1, v+w+u=1, and x+y+z=1. Dry etching of the gallium-containing semiconductor layers is performed to expose sidewalls of the layers. Surface treatments are performed to recover from damage to sidewalls resulting from the dry etching. Dielectric materials are deposited on the sidewalls, for example, by atomic layer deposition (ALD), to passivate the sidewalls. The result is gallium-containing semiconductor layers that have an improvement in optical efficiency as compared to gallium-containing semiconductor layers that are not subjected to the surface treatments and the deposition of the dielectric materials.

### BRIEF DESCRIPTION OF THE DRAWINGS

Referring now to the drawings in which like reference numbers represent corresponding parts throughout:

FIG. 1 is a schematic illustration of a wafer structure before device fabrication;

FIG. 2 is a schematic illustration of a wafer structure after dry etching;

FIG. 3A is a schematic illustration of a III-N device structure, and FIG. 3B is a schematic illustrating a III-P device structure;

FIG. 4 is a graph of relative light output power for 40×40 μm² devices;

FIG. 5 is a graph of relative light output power for 20×20 μm² devices;

FIG. 6 is a graph of efficiency performances for devices with different sidewall treatments;

FIG. 7 is a graph of efficiency loss at 20 A/cm² for 20 μm devices with different sidewall treatments; and

FIG. 8 is a flowchart of the process flow of the invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Overview

This invention describes a method that offers a solution to address the size-dependent efficiency problem, and can suppress the reduction in efficiency of micron-sized LEDs using simple, cost-effective and time-effective, post-etch techniques that are available in a typical cleanroom fabrication environment. By properly applying the method described in this invention, the efficiency of micron-sized LEDs can be recovered to achieve a similar efficiency as larger devices.

### Technical Disclosure

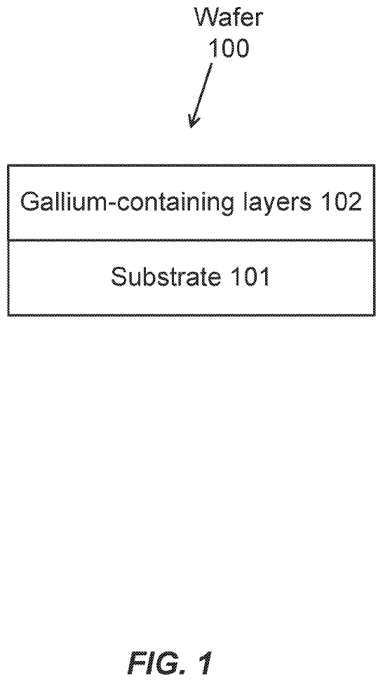

FIG. 1 is a schematic illustrating a wafer 100 comprised of a substrate 101 with gallium-containing layers 102 deposited thereon, wherein the gallium-containing layers 102 of the wafer 100 can have the chemical formula of AlₓGa_{y}In_{z}NᵥP_{w}Asᵤ, where 0≤x≤1, 0≤y≤1, 0≤z≤1, 0≤v≤1, 0≤w≤1, 0≤u≤1, v+w+u=1, and x+y+z=1.

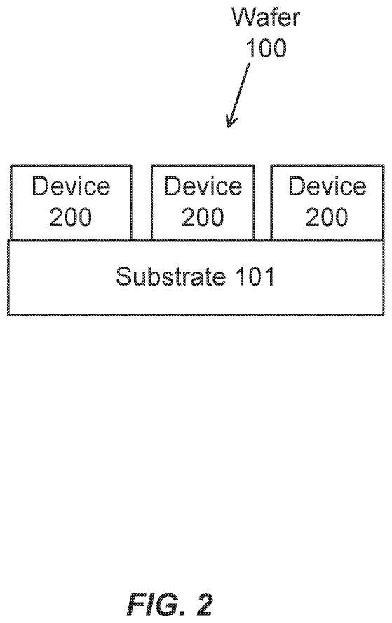

FIG. 2 is a schematic illustrating the wafer 100 after devices 200 have been fabricated on the substrate 101 using the gallium-containing layers 102, and the devices 200 have been selectively etched using dry etching, so that exposed sidewalls of the devices 200 are obtained. The wafer 100 is then treated with thermal annealing and/or sulfur-based or other types of chemicals. The use of thermal annealing and/or sulfur-based or other types of chemicals is to recover the sidewall damage and to passivate the exposed sidewalls to reduce carrier losses caused by non-radiative recombination.

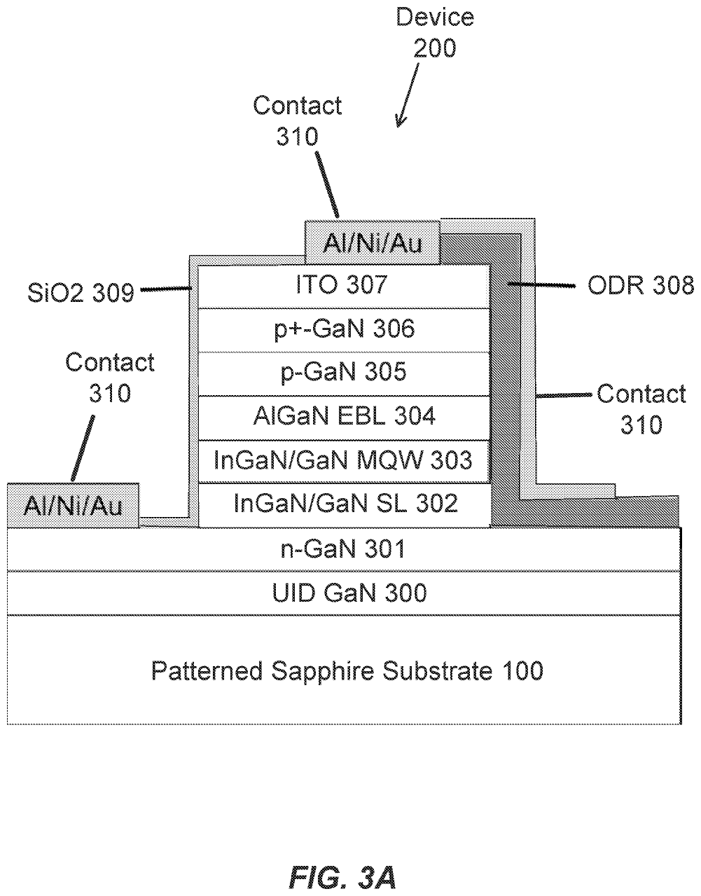

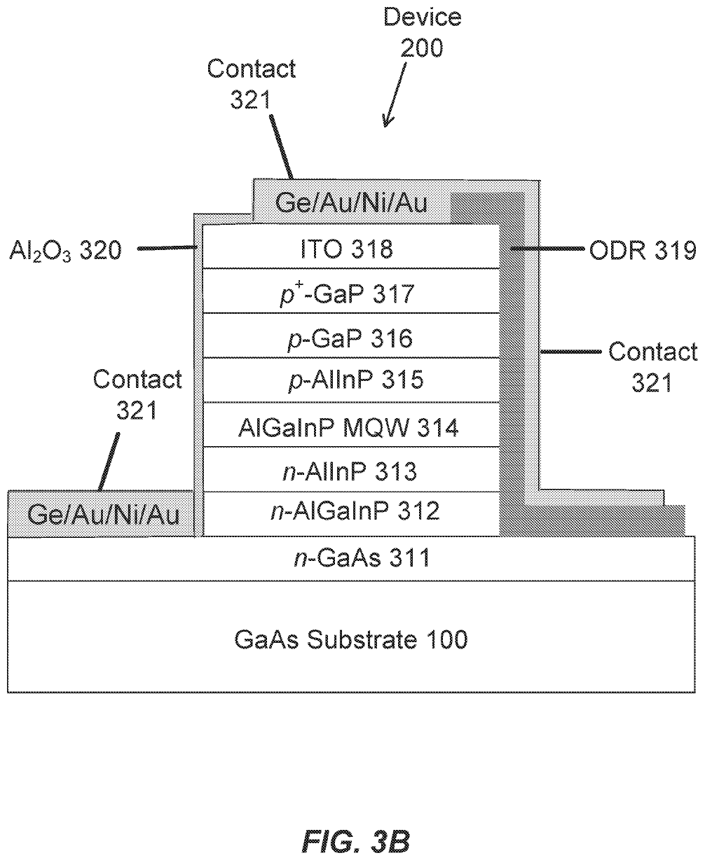

FIG. 3A is a schematic illustrating a fabricated III-nitride device 200 comprising an LED, which includes a patterned sapphire substrate 100, upon which are grown the gallium-containing layers 102, in the order indicated, including: an unintentionally-doped (UID) GaN layer 300, an n-type GaN (n-GaN) layer 301, a 30×InGaN/GaN superlattice (SL) 302, a 6×InGaN/GaN multiple quantum well (MQW) active region 303, an AlGaN electron blocking layer (EBL) 304, a p-type GaN (p-GaN) layer 305, and a highly-doped p+-GaN layer 306. These epitaxial layers were grown by metalorganic chemical vapor deposition (MOCVD).

Devices 200 comprising III-nitride LEDs with different dimensions (lengths) comprising 20×20, 40×40, 60×60, 80×80, and 100×100 μm² were fabricated on the same wafer 100 to minimize growth variation. Before device 200 processing, solvent clean and aqua regia were performed to remove any contaminations on the wafer 100. First, 110 nm of indium-tin oxide (ITO) 307 was deposited using electron-beam evaporation, where the ITO 307 was used as a transparent and ohmic p-contact. After ITO 307 deposition, the light-emitting areas of the devices 200 were defined using dry etching, such as plasma-based dry etching or reactive-ion etching (RIE), to remove portions of the ITO 307 and etch down to the n-GaN layer 301. For devices 200 with chemical treatment, the wafer 100 was treated with KOH solution for 40 minutes at room temperature. An omnidirectional reflector (ODR) 308 comprised of silicon dioxide (SiO₂), tantalum oxide (Ta₂O₅), and aluminum oxide (Al₂O₃) was deposited using ion beam deposition as an isolation dielectric layer for metal deposition. The thickness of each layer in the ODR 309 can be adjusted to have more than 85% reflectance in the blue, green, and red regions, depending on the emission wavelength of PLEDs 200. For devices 200 with sidewall passivation, 50 nm of SiO₂ 309 was deposited using ALD or PECVD, and some of the SiO₂ was removed selectively to open a window using buffered hydrofluoric acid (BHF) for metal deposition. Metal contacts 310 comprised of 700/100/700 nm of Al/Ni/Au were deposited using electron-beam evaporation. The electrical characteristics were then measured using on-wafer testing and the optical efficiency performances were collected from a calibrated integrating sphere by packaging individual devices on silver headers.

FIG. 3B is a schematic illustrating a fabricated III-P device 200 comprising an LED, which includes a GaAs substrate 100, upon which are grown the gallium-containing layers 102, in the order indicated, including: an n-type GaAs (n-GaAs) layer 311, an n-type AlGaInP (n-AlGaInP) layer 312, an n-type AlInP (n-AlInP) layer 313, an AlGaInP MQW active region 314, a p-type AlInP (p-AlInP) layer 315, a p-type GaP (p-GaP) layer 316, and a highly-doped p+-type GaP (p+-GaP) layer 317. These epitaxial layers were grown by MOCVD.

Devices comprising AlGaInP LEDs with different dimensions (lengths) comprising 20×20, 40×40, 60×60, 80×80, and 100×100 μm² were fabricated on the same wafer 100 to minimize growth variation. Before device processing, solvent clean and aqua regia were performed to remove any contaminations on the wafer 100. First, an optional 110 nm of ITO 318 was deposited using electron-beam evaporation as a transparent and ohmic p-contact. After that, the device areas were defined by etching the ITO and AlGaInP materials to the n-type layer. An ODR 319 was deposited using ion beam deposition, which the measured reflectance was about 85% in the 630-650 nm range. For devices with surface pre-treatment prior to ALD sidewall passivation, the wafer was treated with TMA/nitrogen plasma in the ALD chamber. For devices with ALD sidewall passivation, 50 nm of Al₂O₃ 320 was deposited. After ALD sidewall passivation, some of the Al₂O₃ 320 was selectively removed using BHF for metal deposition. The metal stack consisted of 12/80/10/500 nm of Ge/Au/Ni/Au for common p- and n-contacts 321, where the contacts 321 were annealed at 430° C. for 60 seconds after the deposition to achieve better current-voltage characteristics. On-wafer testing was performed to obtain the optical and electrical characteristics of the AlGaInP μLEDs, and the light from the devices was collected using a photodetector that placed vertically on top of the device.

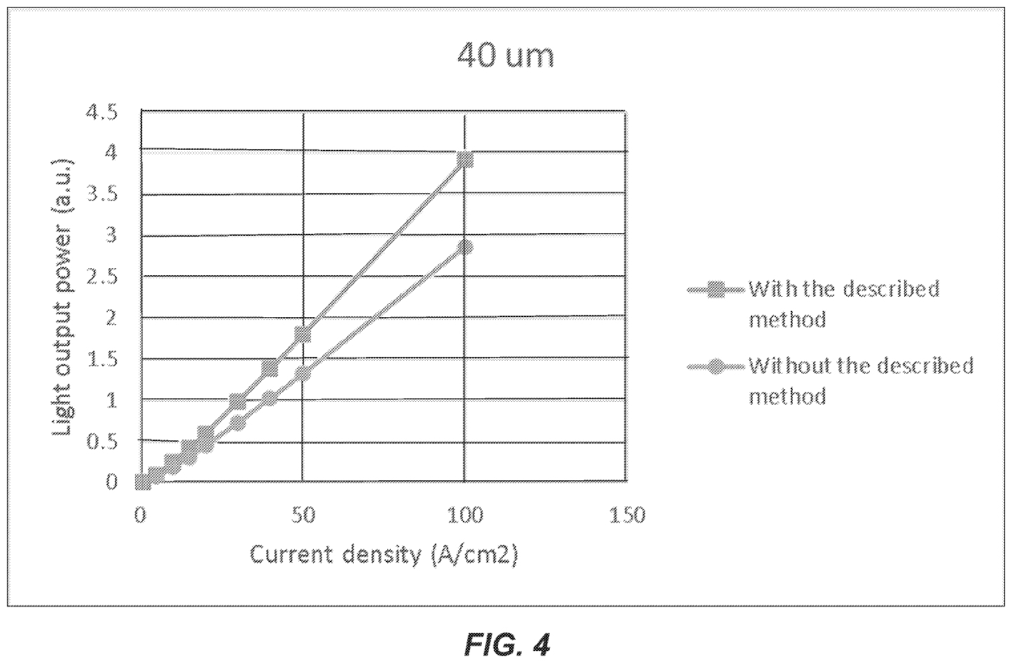

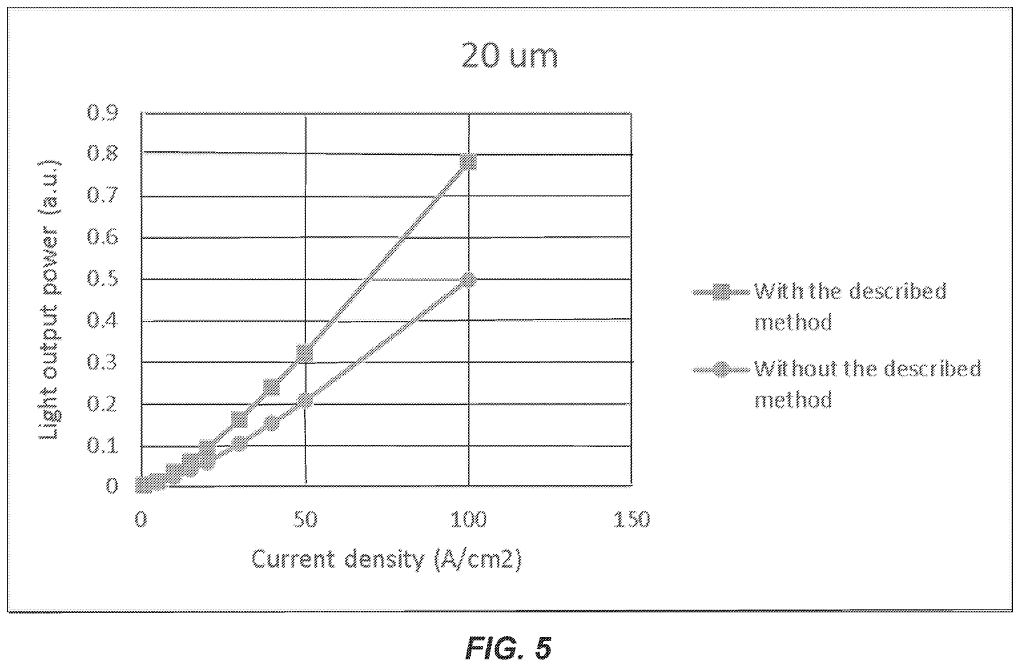

FIGS. 4 and 5 are graphs of light output power (a.u.) vs. current density (A/cm²) for 40×40 and 20×20 μm² devices 200, respectively, with and without the method described above, namely, surface treatments to recover from damage to sidewalls resulting from the dry etching, for example, treating the sidewalls with ammonium sulfide, followed by dielectric sidewall passivation using ALD. Specifically, the relative light output power in both graphs with the method described above is compared to AlGaInPAs devices with only ALD sidewall passivation. The optical improvement from the use of ammonium sulfide and/or other chemicals is significant at any current density, since some applications may require the devices to operate at different (low or high) current density ranges.

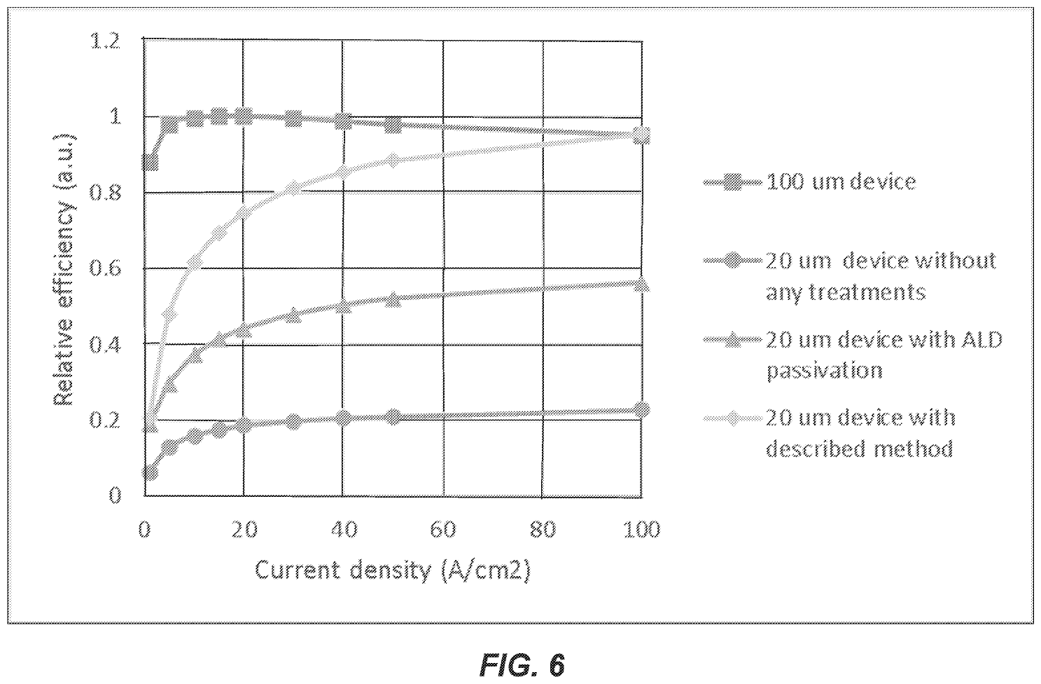

FIG. 6 is a graph of relative efficiency (a.u.) vs. current density (A/cm²) for various devices, including: a 100×100 μm² device, a 20-20 μm² device without any treatments, a 20×20 μm² device with ALD passivation, and 20×20 μm² device treated with the method described above. The plots show the relative efficiency measurements between devices with and without the ammonium sulfide treatment before ALD passivation. To further enhance the efficiency performance, thermal annealing at 320° C. is employed before the ammonium sulfide treatment and ALD sidewall passivation. Thermal annealing increases the efficiency further and the efficiency of the 20×20 μm² device can achieve the same efficiency as the 100×100 μm² device.

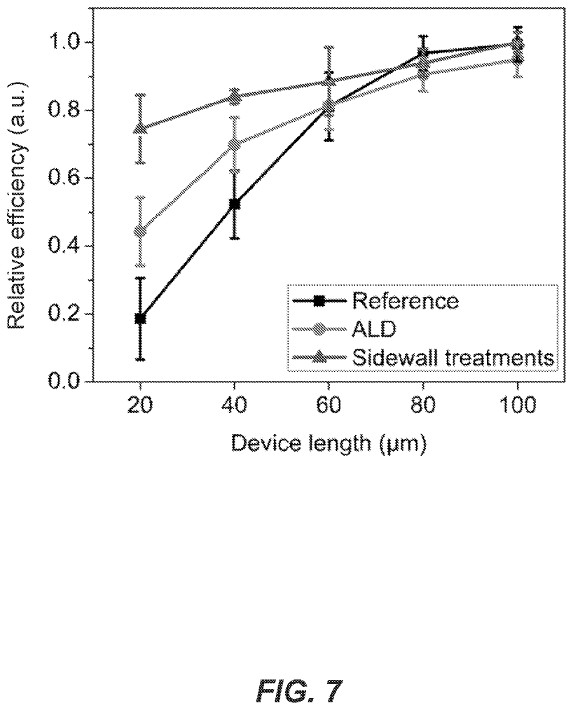

FIG. 7 is a graph of relative efficiency (a.u.) vs. device length (μm) that shows how efficiency drops with shrinking device dimensions, and more specifically, the decrease in efficiency at 20 A/cm² for reference, ALD and sidewall treatments.

Process Flow

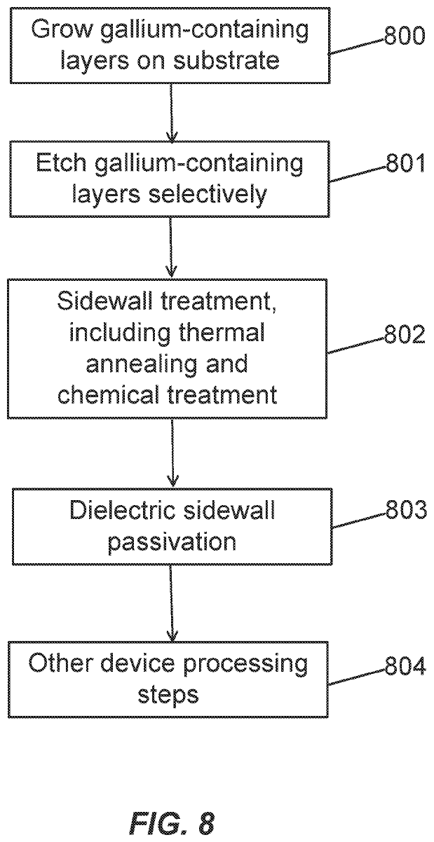

FIG. 8 is a flowchart of the process steps of the invention described above.

Block 800 represents the step of growing one or more gallium-containing semiconductor layers on a substrate. The gallium-containing semiconductor layers comprise AlₓGa_{y}In_{z}NᵥP_{w}Asᵤ, where 0≤x≤1, 0≤y≤1, 0≤z≤1, 0≤v≤1, 0≤w≤1, 0≤u≤1, v+w+u=1, and x+y+z=1. More specifically, the gallium-containing semiconductor layers have one or more of nitrogen, phosphorus, or arsenic as counter atoms.

Block 801 represents the step of dry etching of the gallium-containing semiconductor layers to expose sidewalls of the layers.

Block 802 represents the step of performing one or more surface treatments to the sidewalls to recover from damage to the sidewalls resulting from the dry etching. In one embodiment, the surface treatments comprise thermal annealing at temperatures above 40° C. and then treating the sidewalls with a chemical that contains either oxygen, hydrogen or sulfur atoms. In another embodiment, the surface treatments comprise performing a chemical treatment at temperatures above 40° C. The surface treatments may comprise a liquid, gas, or plasma, such as ammonium sulfide for sulfidation, potassium hydroxide for oxidation, and/or ultra-violet (UV) ozone plasma for oxidation. For example, the surface treatments may comprise treating the sidewalls with ammonium sulfide after thermal annealing at temperatures greater than 40° C. In addition, the surface treatments may be performed at ambient conditions or at elevated temperatures less than 200° C.

Block 803 represents the step of depositing one or more dielectric materials on the sidewalls to passivate the sidewalls of the device, after the surface treatments have been performed. The dielectric materials may be deposited using ALD, sputtering, or another physical or chemical vapor deposition. The dielectric materials may be conformal or uniformly cover the sidewalls.

Block 804 represents the step of performing other device processing steps.

The end result of the method is a device where the gallium-containing semiconductor layers have an improvement in optical efficiency as compared to gallium-containing semiconductor layers that are not subjected to the performing of the surface treatments and the depositing of the dielectric materials.

### REFERENCES

The following publications are incorporated by reference herein:
1. High Performance of AlGaInP Red Micro-Light-Emitting Diodes with Sidewall Treatments, Optics Express, 28(4), 5787 (2020).
2. Size-independent Peak Efficiency of III-Nitride Micro-Light-Emitting Diodes using Chemical Treatment and Sidewall Passivation, Applied Physics Express, 12, 097004 (2019).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1-12. (canceled)

13. A device, comprising:
one or more gallium-containing semiconductor layers grown on a substrate, wherein:
the gallium-containing semiconductor layers are dry-etched to expose sidewalls of the layers;
one or more surface treatments are performed on the sidewalls to recover from damage to the sidewalls resulting from the dry etch; and
one or more dielectric materials are deposited on the sidewalls to passivate the sidewalls, after the surface treatments are performed.

14. The device of claim 13, wherein the surface treatments comprise thermal annealing at temperatures above 40° C. and then treating the sidewalls with a chemical that contains either oxygen, hydrogen, or sulfur atoms.

15. The device of claim 13, wherein the surface treatments comprise a chemical treatment performed at temperatures above 40° C.

16. The device of claim 13, wherein the surface treatments comprise a liquid, gas, or plasma, such as ammonium sulfide for sulfidation, potassium hydroxide for oxidation, and/or ultra-violet (UV) ozone plasma for oxidation.

17. The device of claim 13, wherein the surface treatments comprise treating the sidewalls with ammonium sulfide after thermal annealing at temperatures greater than 40° C.

18. The device of claim 13, wherein the surface treatments are performed at ambient conditions or at elevated temperatures less than 200° C.

19. The device of claim 13, wherein the dielectric materials are deposited using atomic layer deposition (ALD), sputtering, or another physical or chemical vapor deposition.

20. The device of claim 13, wherein the dielectric materials are conformal or uniformly cover the sidewalls.

21. The device of claim 13, wherein the gallium-containing semiconductor layers have an improvement in optical efficiency as compared to gallium-containing semiconductor layers that are not subjected to the performing of the surface treatments and the depositing of the dielectric materials.

22. The device of claim 13, wherein the gallium-containing semiconductor layers comprise AlₓGa_{y}In_{z}NᵥP_{w}Asᵤ, where 0≤x≤1, 0≤y≤1, 0≤z≤1, 0≤v≤1, 0≤w≤1, 0≤u≤1, v+w+u=1, and x+y+z=1.

23. The device of claim 22, wherein the gallium-containing semiconductor layers have one or more of nitrogen, phosphorus, or arsenic as counter atoms.
